(19) United States
(12) Patent Application Publication
(10) Pub. No.: US 2026/0009868 A1
(43) Pub. Date: Jan. 8, 2026

(54) SENSOR SYSTEM HAVING AN IRREGULAR ARRANGEMENT OF DIAMOND PILLARS WITH NITROGEN VACANCY CENTERS AND ASSOCIATED METHODS

(71) Applicant: Eagle Technology, LLC, Melbourne, FL (US)

(72) Inventors: Scott RAUSCHER, Washington, DC (US); Haley STUMVOLL, West Melbourne, FL (US); James A. DRAKES, Occoquan, VA (US); Fraser R. DALGLEISH, Vero Beach, FL (US); Nicholas ALBAN, Palm Bay, FL (US); Donna M. KOCAK, Satellite Beach, FL (US)

(21) Appl. No.: 18/765,395

(22) Filed: Jul. 8, 2024

(51) Int. Cl. G01R 33/032

(52) U.S. Cl. CPC G01R 33/032

(57) ABSTRACT

A sensing system may include a sensor substrate and a plurality of diamond pillars on the sensor substrate in an irregular arrangement. Each diamond pillar may include at least one nitrogen vacancy center (NVC) and a respective pair of input and output optical waveguides coupled to each diamond pillar. At least some of the pillars may have different heights, and different height shims may be coupled between the sensor substrate and adjacent portions of the corresponding input and output optical waveguides.

### FIELD OF THE INVENTION

The present invention relates to the field of sensing systems, and, more particularly, to sensing systems using at least one nitrogen vacancy center (NVC) and related methods.

### BACKGROUND OF THE INVENTION

A nitrogen vacancy center (NVC) in diamond may be a promising platform for many applications in quantum technologies. The atom-like energy level structure of the nitrogen vacancy center makes it a vector magnetometer at a sub-nanotesla spatial scale for measuring one or more components of a magnetic field.

A useful property of the nitrogen vacancy center is its photoluminescence, which allows observers to read out its spin-state. Full state control in the nitrogen vacancy center spin manifold has been realized through several technologies, including magnetic, optical, and mechanical methods. The manipulation of the nitrogen vacancy center within its excited-state orbital manifold, such as modified by magnetic fields, electric fields, temperature, and strain allows it to serve as a sensor for a variety of physical phenomena. Thus, its atomic size and spin properties can form the basis for useful quantum centers.

One proposal for employing nitrogen vacancy centers in sensor applications is described in the article by McCloskey, et al., “Enhanced Widefield Quantum Sensing with Nitro-Vacancy Ensembles Using Diamond Nanopillar Arrays,” ACS Appl Mater Interfaces; Mar. 18, 2020; pp. 13421-13427, the disclosure which is hereby incorporated by reference in its entirety. This article describes surface micro- and nano-patterning techniques on a bulk diamond substrate to enhance an optical interface to single photoluminescent emitters for a sensor, which includes closely packed arrays of florescent same height diamond nano-pillars, each hosting its own dense, uniformly bright ensemble of near-surface nitrogen vacancy centers. The uniform N by N array increases the optically detected magnetic resonant sensitivity when compared to an unpatterned surface. The article discusses the authors' findings that the fabrication process has a negligible impact on in-built stresses compared to an unpatterned surface. However, this ordered array of same height nano-pillars, each having its own ensemble of near-surface nitrogen vacancy centers, has been found limiting in function and may be difficult to address numerous nitrogen vacancy centers in one nano-pillar.

### SUMMARY OF THE INVENTION

In general, a sensing system may comprise a sensor substrate and a plurality of diamond pillars on the sensor substrate in an irregular arrangement. Each diamond pillar may comprise at least one nitrogen vacancy center (NVC). A respective pair of input and output optical waveguides may be coupled to each diamond pillar.

At least some of the diamond pillars may have different heights. Respective different height shims may be coupled between the sensor substrate and adjacent portions of the corresponding input and output optical waveguides. The plurality of input and output optical waveguides may be arranged in parallel rows. The sensor substrate may comprise a diamond substrate. The diamond substrate may comprise a bulk diamond substrate, and the plurality of diamond pillars may be integrally formed with the bulk diamond substrate.

A sensing circuit may be coupled to the plurality of input and output optical waveguides. A Photonic Integrated Circuit (PIC) substrate may support the sensor substrate. Each input optical waveguide may comprise an input optical fiber and an input photonic wire bond coupling the input optical fiber to the corresponding diamond pillar. Each output optical waveguide may comprise an output optical fiber and an output photonic wire bond coupling the output optical fiber to the corresponding diamond pillar.

Another aspect is directed to a method of making a sensing device that may comprise forming a plurality of diamond pillars on a sensor substrate in an irregular arrangement, each diamond pillar comprising at least one nitrogen vacancy center (NVC). The method may further include coupling a respective pair of input and output optical waveguides to each diamond pillar.

### BRIEF DESCRIPTION OF THE DRAWINGS

Other objects, features and advantages of the present invention will become apparent from the detailed description of the invention which follows, when considered in light of the accompanying drawings in which:

FIG. 1 is a plan view of the sensing system having diamond pillars, each with at least one nitrogen vacancy according to the invention.

FIG. 2 is a schematic, partial sectional view of the sensing system of FIG. 1.

FIG. 3 is another schematic, partial sectional view of the sensing system of FIG. 1 showing an example input and output optical waveguide.

FIG. 4 is a schematic partial plan view of the sensor system of FIG. 1 showing some diamond pillars having more than one nitrogen vacancy center.

FIG. 5 is another schematic, partial sectional view of the sensor system that includes a resonating magnet under a nitrogen vacancy center.

FIG. 6A is a schematic plan view of the sensor substrate showing irregularly arranged nitrogen vacancy centers therein.

FIG. 6B is a schematic sectional view of the sensor substrate taken a long line 6B-6B of FIG. 6A showing the irregularly arranged nitrogen vacancy centers.

FIG. 6C is a schematic, plan view of the sensor substrate of FIG. 6A showing the photomask pattern used for etching.

FIG. 7 is a schematic, sectional view of the sensor substrate after etching showing three etch levels for the diamond pillars, each having a nitrogen vacancy center.

FIG. 8 is a flowchart showing a method of making the sensing device according to the invention.

FIG. 9 is a schematic, sectional view of the sensing system without diamond pillars where an optical detector is associated with each nitrogen vacancy center in the sensor substrate according to another embodiment of the invention.

FIG. 10 is another schematic, sectional view of the sensing system of FIG. 9 showing an optical detector.

FIG. 11 is a schematic, partial isometric view of optical focusing elements for focusing the optical beams.

FIG. 12 is a table showing the spot size and minimum separation of nitrogen vacancy centers to permit independent interrogation.

FIG. 13 is a high-level flowchart showing a method of making the sensing device of FIG. 9.

### DETAILED DESCRIPTION

The present description is made with reference to the accompanying drawings, in which exemplary embodiments are shown. However, many different embodiments may be used, and thus, the description should not be construed as limited to the particular embodiments set forth herein. Rather, these embodiments are provided so that this disclosure will be thorough and complete. Like numbers refer to like elements throughout.

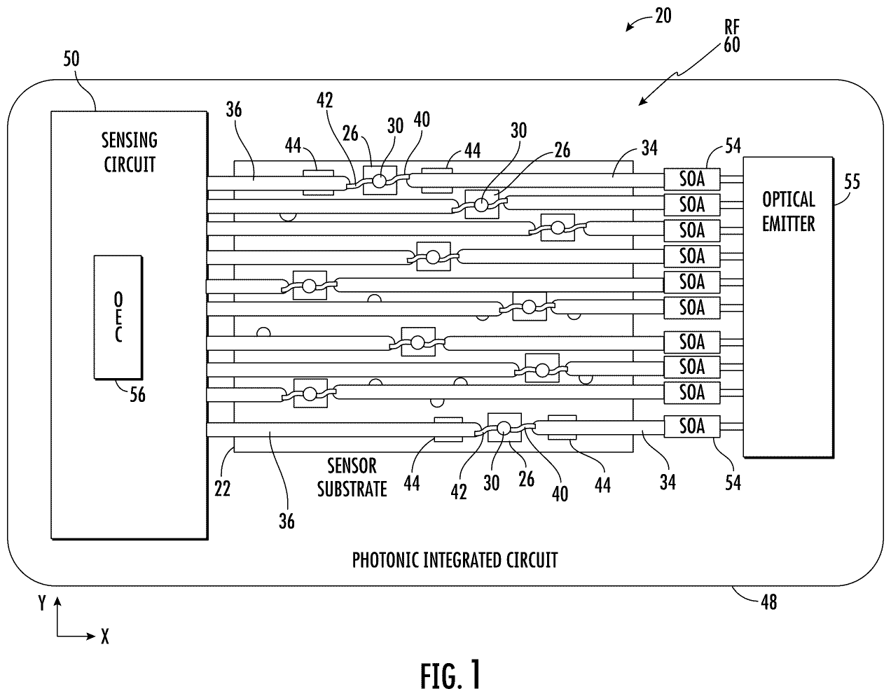

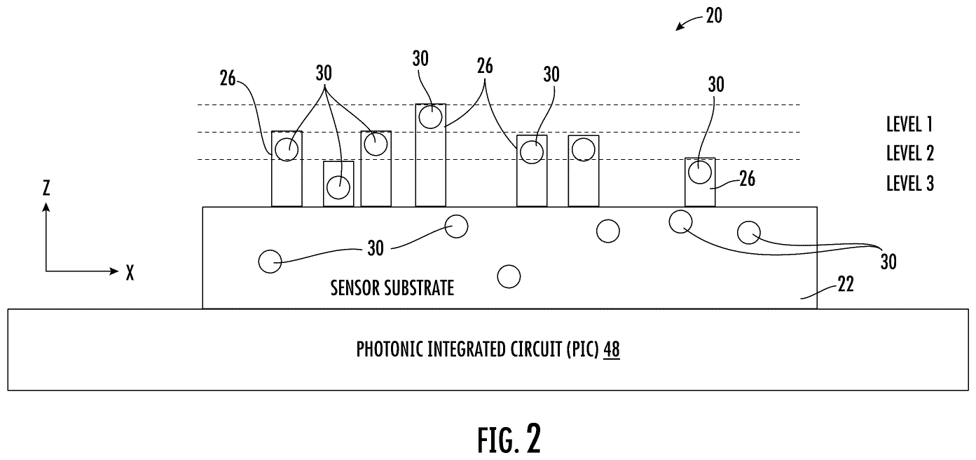

Referring now to FIGS. 1-3, there is illustrated a sensing system shown generally at 20 that includes a sensor substrate 22 and a plurality of diamond pillars 26 on the sensor substrate in an irregular arrangement, such as shown in FIGS. 1 and 2. Taken together, the plan view in FIG. 1 and sectional view in FIG. 2 show the irregular arrangement of the diamond pillars in the X, Y and Z directions. Each diamond pillar 26 includes at least one nitrogen vacancy center (NVC) 30 as shown by the darkened circle in the top portion of each diamond pillar.

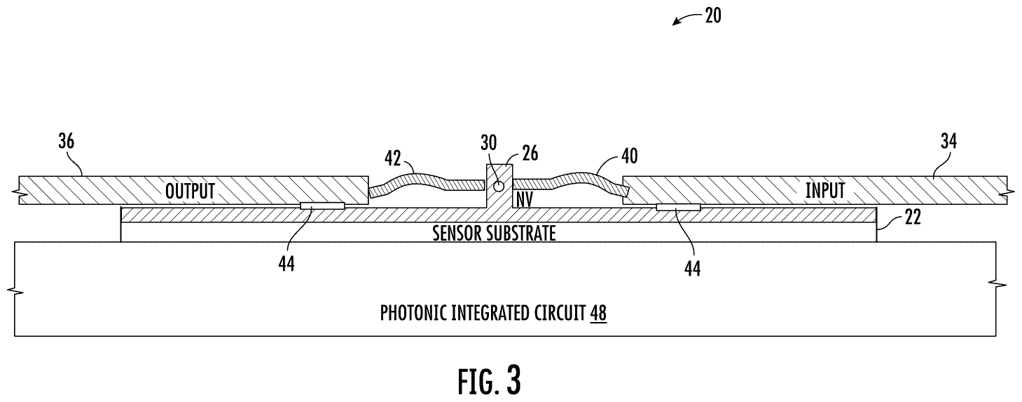

As best shown in FIGS. 1 and 3, a respective pair of input and output optical waveguides 34,36 are coupled to each diamond pillar 26. In a non-limiting example, each input optical waveguide 34,36 may be formed as an input optical fiber having an input photonic wire bond 40 coupling the input optical fiber to the corresponding diamond pillar 26. Each output optical waveguide 36 may be formed as an output optical fiber and an output photonic wire bond 42 coupling the output optical fiber to the corresponding diamond pillar 26.

As shown in the partial sectional view of FIG. 2, at least some of the diamond pillars 26 have different heights and accommodate different levels of optical waveguides 34,36 as optical fiber levels, shown as fiber levels 1, 2 and 3. Respective different height shims 44 may be coupled between the sensor substrate 22 and adjacent portions of the corresponding input and output optical waveguides 34,36 with examples shown in FIG. 1 where height shims are shown adjacent the two outermost diamond pillars 26. The height shims 44 may be formed by photolithography and etching as explained in greater detail below or by inserting separate height shims in position on the sensor substrate 22 before the optical waveguides 34,36 are positioned. These input and output optical waveguides 34, 36 as example optical fibers may be arranged in parallel rows as shown in FIG. 1.

The sensor substrate 22 may be formed from a bulk diamond substrate, and the diamond pillars 26 may be integrally formed with the bulk diamond substrate. The nitrogen vacancy centers 30 may be distributed in an irregular arrangement through the bulk diamond substrate 22 as shown in FIG. 2. The irregular arrangement may be a random arrangement. As explained in greater detail below, the nitrogen vacancy centers 30 are identified and isolated, for example, by ion mill etch-back of the NVC-populated bulk diamond substrate 22, which isolates the nitrogen vacancy centers on the diamond pillars 26.

The sensor substrate 22 may be supported on a photonic integrated circuit (PIC) substrate 48 as shown in FIG. 1, and a sensing circuit 50 coupled to the plurality of input and output optical waveguides 34,36 as optical fibers. As a non-limiting example, the input waveguides 34 as optical fibers may each be connected to a semiconductor optical amplifier (SOA) 54. Input optical signals generated from an optical emitter 55 may be amplified by each semiconductor optical amplifier 54 and passed through the nitrogen vacancy centers 30 in the diamond pillars 26. Each optical signal may be output from the output optical fibers 42 into another semiconductor optical amplifier (not shown) or directly into photonic circuitry, such as the sensing circuit 50, which operates as the sensor for the physical phenomena being measured by the impact on the nitrogen vacancy centers 30. The sensing circuit may include an optical-to-electrical converter (OEC) 56 that converts optical signals into electrical signals for processing.

In FIG. 1, an RF signal 60 is shown that modifies the nitrogen vacancy center 30 energy levels, which are then processed at the sensing circuit 50 based upon the impacted optical signals from the output optical waveguides 36. However, other physical parameters may be sensed and measured instead of an RF signal 60, such as temperature, strain and variations of magnetic and electric fields as will be understood by those skilled in the art.

The diamond pillar 26 dimensions can vary from about 50 to about 500 nanometers wide, and in height may vary from a low of about 100 nanometers to as high as about 200 micrometers. Each input and output optical waveguide 34,36 formed as an optical fiber may vary, but in an example, may be about 200 microns in diameter. The bulk diamond substrate 22 may vary in its dimensions, but in an example, it may be about 3 millimeters by 3 millimeters and support from five (5) input and output optical waveguides 34,36 up to about 50 input and output optical waveguides into and from the respective diamond pillars 26.

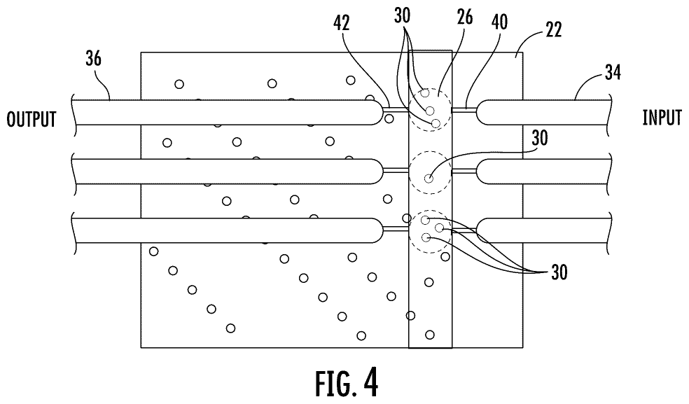

FIG. 4 is a partial schematic plan view of the sensing system 20 where diamond pillars 26 contain one or more nitrogen vacancy centers 30 that are intended for interrogation from a single input optical waveguide 34 as an optical fiber. In this non-limiting example, three (3) diamond pillars 26 are illustrated with the center diamond pillar having one (1) nitrogen vacancy center 30 and the two outer diamond pillars each having three (3) nitrogen vacancy centers.

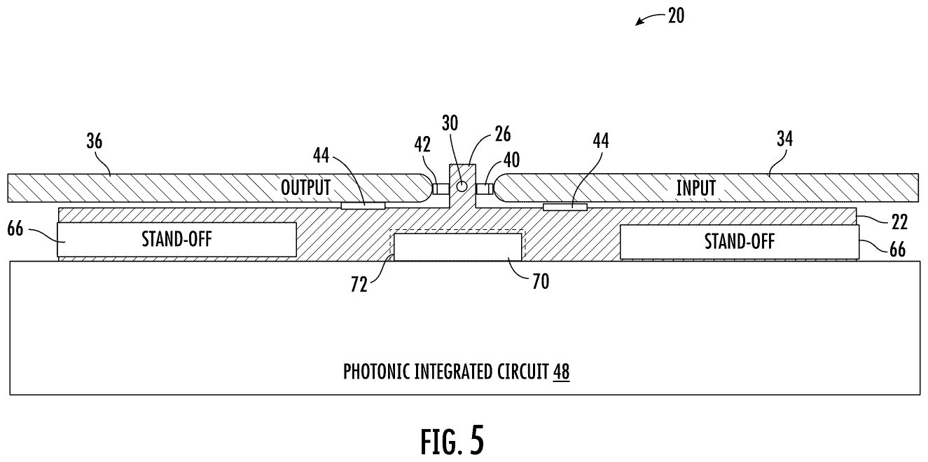

A resonating magnet 70 may be added as shown in the partial, sectional view of the sensing system in FIG. 2, FIG. 5, where a precise stand-off 66 has been formed during the etching process or may be deposited or separately inserted and used to isolate one or more diamond pillars 26 and any nitrogen vacancy center 30. The resonating magnet 70 may be contained in a cavity 72 formed in the sensor substrate 22 and may move up and down as the nitrogen vacancy center 30 is engaged from an RF or other electrical or magnetic field. The movement of the resonating magnet 70 may be measured to aid in sensing and measuring the RF or other electrical or magnetic field. The oscillating magnet 70 may be aligned and supported with parallel edge alignment, and the precisely deposited stand-offs 66 made by layering, and the magnet positioned by pick-and-place precision chip-bonding to place it onto the photonic integrated circuit substrate.

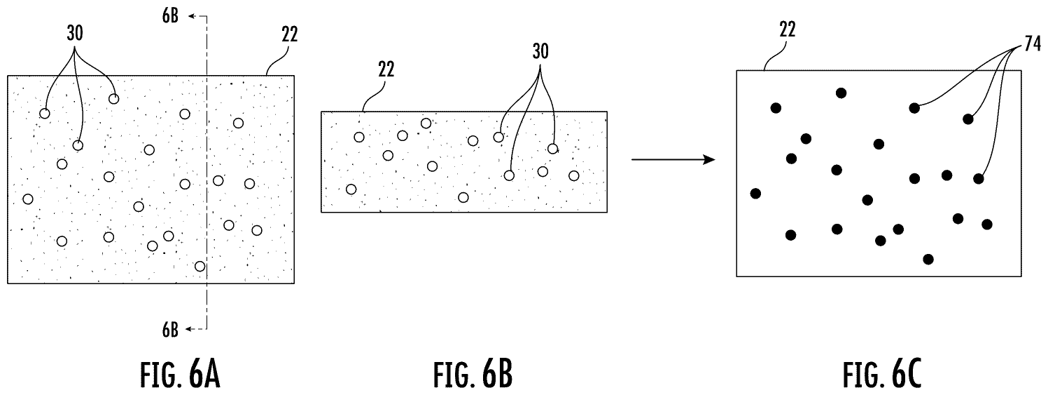

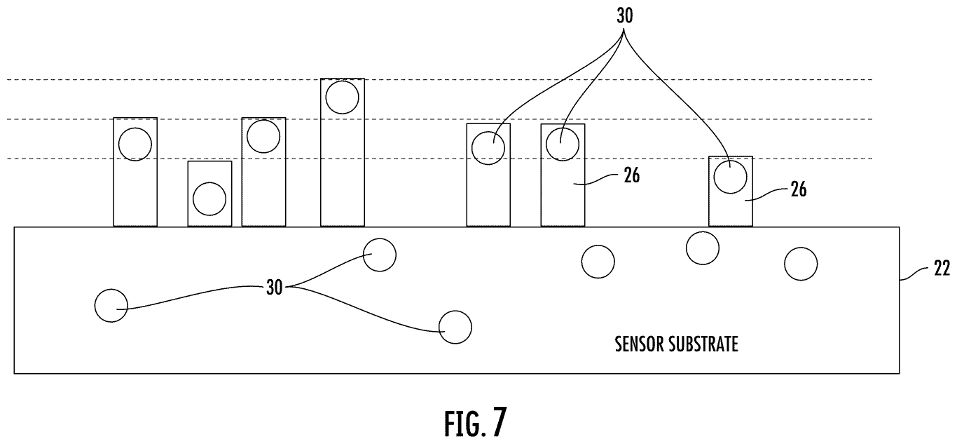

Referring now to the images of FIGS. 6A, 6B, 6C, and 7, a basic sequence in the manufacture of the diamond pillars 26 is illustrated. The diamond substrate 22 is shown in its top and side views (FIGS. 6A and 6B) and has irregularly arranged nitrogen vacancy centers 30, which may be randomly distributed. The location of one or more nitrogen vacancy centers 30 in the entire population within the diamond substrate 22 are identified, e.g., by scanning laser illumination, sensing the resulting output spectra, and then cataloging the three-dimensional source locations of the nitrogen vacancy centers. Any selected nitrogen vacancy centers 30 are spatially isolated for interrogation, for example, by ion mill etch-back of the diamond substrate 22 with a photolithographically defined hard mask as shown by the pattern in FIG. 6C, where the black dots 74 are masked areas. Controlled etching of the sensor substrate 22 forms the diamond pillars 26 as shown in FIG. 7, with each diamond pillar including a nitrogen vacancy center 30.

As explained above, the isolated nitrogen vacancy centers 30 are illuminated, for example, by light guided through the input and output optical waveguides 34,36, e.g., the optical fibers, using the input and output photonic wire bonds 40,42 at the physical and optical connections. The optical input may be green light, and after passing through and energizing the nitrogen vacancy centers 30, emerge as red light since the green light having greater energy will energize the nitrogen vacancy center 30 and lose energy to become the red wavelength. Optical loss can be minimized by an angled ion mill etch polishing of the diamond pillar 26 side walls prior to optical connection of the optical fibers 34,36. Optionally, it is possible to add reflective coatings on the side walls of the diamond pillars 26, or add optical filters to condition the input and output signals.

During formation of the diamond pillars 26, the bulk diamond substrate 22 may be scanned with an active laser to measure the size of projected spectra circle, followed by blanket etching, measuring the change in output spectra size, and then determining depth for a second blanket etch, such that the nitrogen vacancy center 30 being interrogated will be near the surface. Measuring the output spectra again may enable more precise identification for photolithography patterning around any identified nitrogen vacancy center areas that will be etched.

It is also possible to first etch with an ion mill and hard mask an array of indiscriminate diamond pillars 26 into the surface of the diamond substrate 22 that are spaced sufficiently apart such that the output spectra of the interrogated diamond pillars will likely not overlap with adjacent pillars. It is possible to raster an input laser across the array of diamond pillars 26 to determine which pillars contain a nitrogen vacancy center 30, indicated by the spectral output, and then create a corresponding photomask to mask the identified nitrogen vacancy centers. The etching may remove unoccupied diamond pillars 26, leaving the isolated diamond pillars with their nitrogen vacancy centers 30 for isolated interrogation.

In the sensor system 20, the photonic integrated circuit substrate 48 as a chip may include different conditioning optical components to support optical sensing processing, including conversion into electrical signals, and enable green light modulation for the input, while allowing red light output and measurement for optical processing. The photonic integrated circuit substrate 48 as a chip may be optically connected to the diamond pillars 26 and nitrogen vacancy centers 30 by the photonic wire bonds 40,42 at the ends of the optical fibers 34,36, or in another example, by a sufficiently tolerant, fiber block with a V-groove alignment (not shown). For example, V-groove slots may be spatially aligned to the face of a nitrogen vacancy center 30 in its diamond pillar 26 by using a deep silicon etch of the adjacent sensor substrate 22 to create a slot at the location of the nitrogen vacancy center, followed by adhesive bonding, all with a sufficient tolerance such that the V-groove and optical fibers effectively cover the surface of the nitrogen vacancy centers.

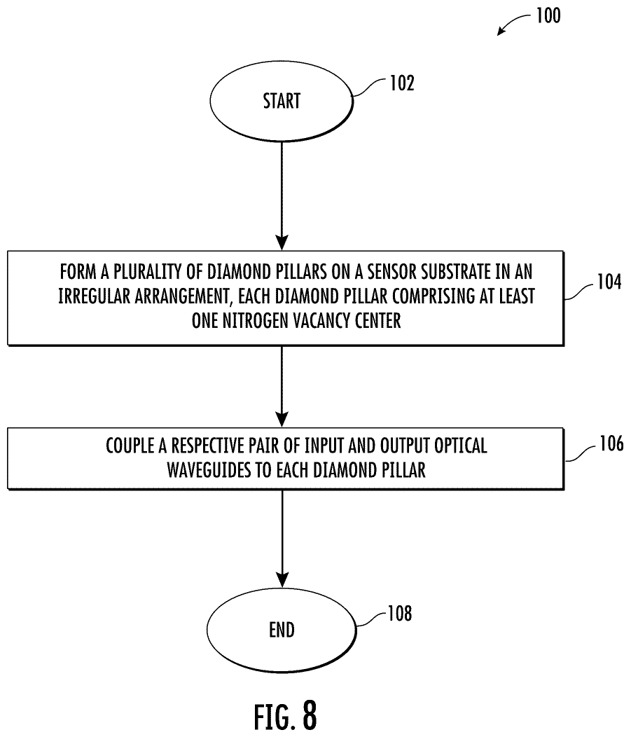

Referring now to FIG. 8, there is illustrated generally at 100 a flowchart showing a method of making a sensing device 20. The method starts (Block 102) and includes forming a plurality of diamond pillars 26 on a sensor substrate 22 in an irregular arrangement, each diamond pillar comprising at least one nitrogen vacancy center 30 (Block 104). The method further includes coupling a respective pair of input and output optical waveguides 34,36 to each diamond pillar 26 (Block 106). The process ends (Block 108).

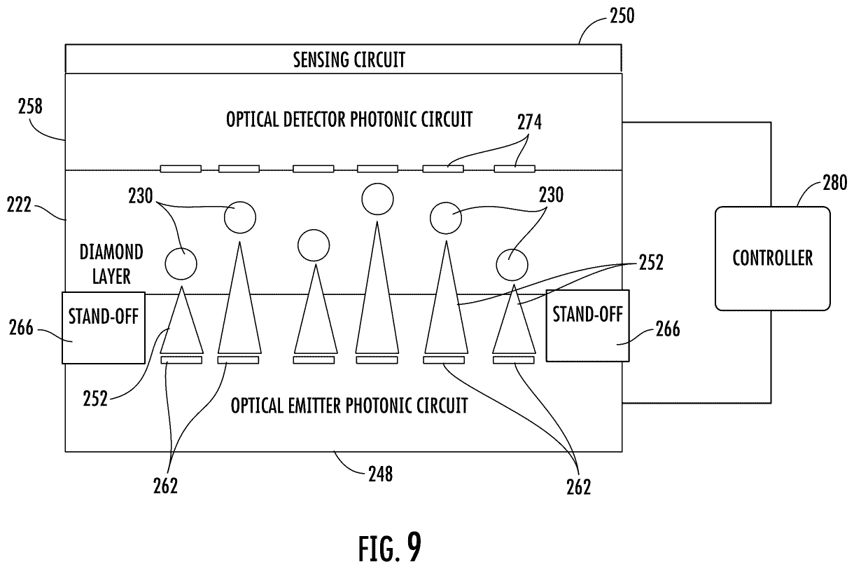

Referring now to FIGS. 9-11, there is shown another example of a sensor system illustrated generally at 200, which does not employ diamond pillars 26 as in the sensor system 20 shown in FIGS. 1-5. However, this sensor 200 system takes advantage of the bulk diamond substrate as a diamond layer 222 having nitrogen vacancy centers 230 that are irregularly arranged at different depths within the diamond layer.

The diamond layer 222 incorporates an optical emitter photonic circuit 248 that is configured to generate a plurality of focused optical beams 252 as the input optical beam. A first side of the diamond layer 222 is adjacent the optical emitter photonic circuit 248. This diamond layer 222 includes the nitrogen vacancy centers 230 aligned with respective focused optical beams 252 generated from the optical emitter photonic circuit. An optical detector photonic circuit 258 is adjacent a second side of the diamond layer 222 opposite the first side and detects the optical beams after energizing the nitrogen vacancy centers 230.

The optical emitter photonic circuit 248 may incorporate an array of vertically firing, green light input surface emitters 262, which focus the green light optical beams through respective nitrogen vacancy centers 230 and energize the nitrogen vacancy centers. Energy is absorbed at each nitrogen vacancy center 230, and the emitted red light is detected by the optical detector photonic circuit 258 adjacent the second side of the diamond layer 222 opposite the first side as shown in FIG. 9. A sensing circuit 250 is coupled to the optical detector photonic circuit 258 and may operate similar in function to the sensing circuit 50 for the sensor system 20 shown in FIG. 1, and provide optical signal sensing and further processing.

The optical emitter photonic circuit 248 may include the green light surface emitters 262, each formed in an example as a vertical coupler utilizing a 45-degree mirror, e.g., a lensed mirror, such that the focal distance may be controlled for each of the emitters. Spacers, such as the illustrated stand-offs 266, may position the optical emitter photonic circuit 248 a specified distance from the diamond layer 222 to aid in obtaining a correct focal length and spot size for the focused optical beams. The specified focal lengths and spot sizes address specified nitrogen vacancy centers 230 without requiring diamond substrate etching. The optical detector photonic circuit 258 may include, as shown in FIG. 9, an array of photodetectors 274 as part of a photonic integrated circuit that captures each nitrogen vacancy center 230 output. An example for each photodetector 274 may be a silicon/germanium detector. A controller 280 may be connected to both the optical emitter photonic circuit 248 and optical detector photonic circuit 258 and control operation of both circuits.

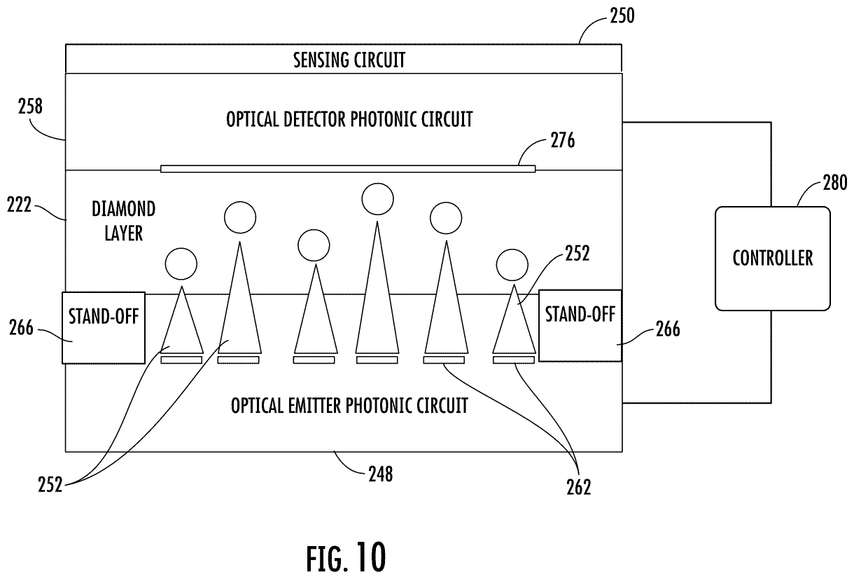

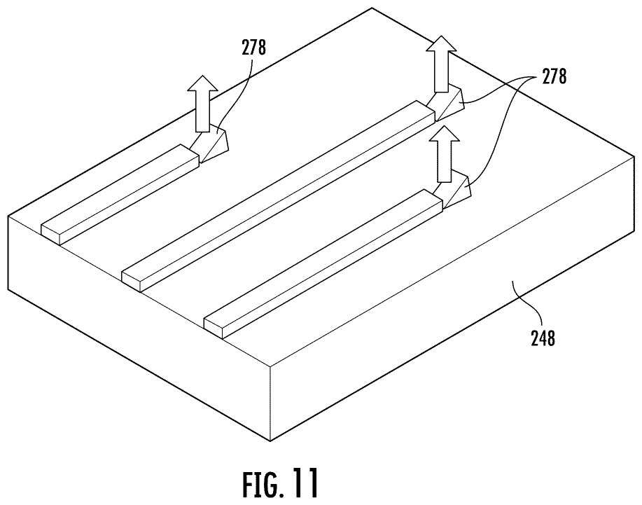

In the example of FIG. 10, a single photodetector 276 may capture the summation of the optical energy from the outputs of the nitrogen vacancy centers 230 either on a photonic integrated circuit surface, or a mounted POTS detector, such as a silicon germanium detector. As shown in the partial schematic, isometric of the optical emitter photonic circuit 248 in FIG. 11, grayscale 45-degree mirrors 278 may be located within the optical emitter photonic circuit 248 and contain curved lens surfaces with varying focal distances to address specific three-dimensional locations where the nitrogen vacancy centers 230 are irregularly located in the diamond layer 222. The green input light may be generated at the optical emitter photonic circuit 248 against the mirrors 278 as illustrated.

It is also possible to inject light into photonic integrated circuit waveguides by edge coupling or using other vertical grating/mirror inputs. The specific three-dimensional location of the nitrogen vacancy centers 230 can be determined by the same technique, such as described above.

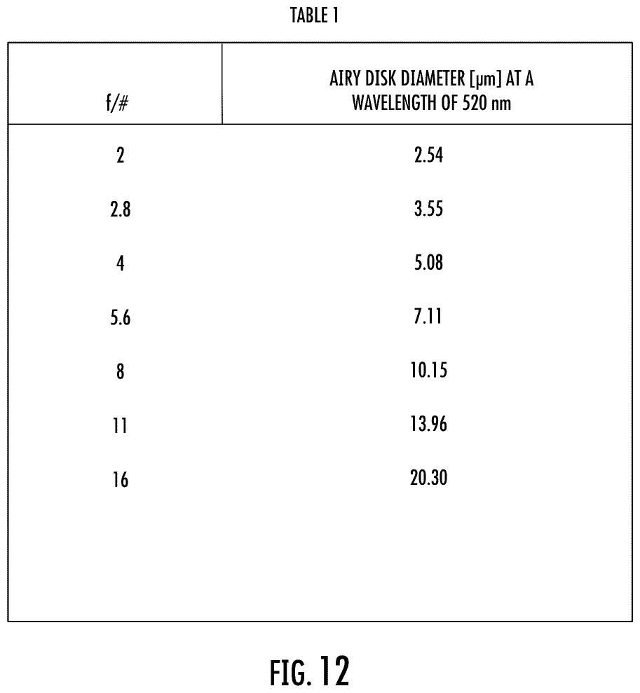

Table 1 shown in FIG. 12 illustrates a minimum spot size or Airy disk, which may be used to indicate a minimum separation of nitrogen vacancy centers 230 that would permit independent interrogation showing how the minimum spot size, or Airy disk, increases with the f-number indicative of the amount of incoming light and can quickly surpass pixel size.

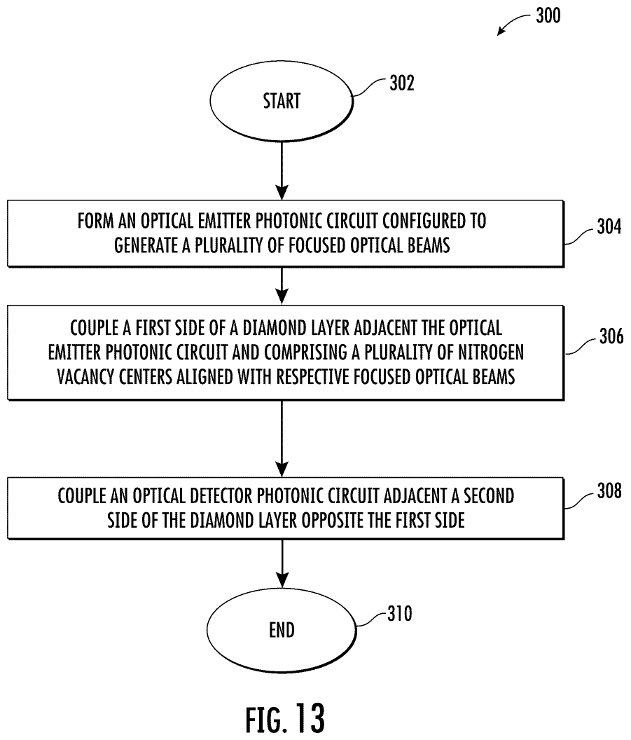

Referring now to FIG. 13, there is illustrated generally at 300 a method of making the sensing device 200. The process starts (Block 302). The method includes forming an optical emitter photonic circuit 248 configured to generate a plurality of focused optical beams 252 (Block 304). The method includes coupling the first side of a diamond layer 222 adjacent the optical emitter photonic circuit 248, where the diamond layer comprises a plurality of nitrogen vacancy centers 230 aligned with respective focused optical beams 252 (Block 306). The method further includes coupling an optical detector photonic circuit 258 adjacent a second side of the diamond layer 222 opposite the first side (Block 308), and ends at Block 310.

This application is related to copending patent application entitled, “SENSOR SYSTEM HAVING NITROGEN VACANCY CENTERS ALIGNED WITH FOCUSED OPTICAL BEAMS,” which is filed on the same date and by the same assignee, the disclosure of which is hereby incorporated by reference.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1. A sensing system comprising:
a sensor substrate;
a plurality of diamond pillars on the sensor substrate in an irregular arrangement, each diamond pillar comprising at least one nitrogen vacancy center (NVC); and
a respective pair of input and output optical waveguides coupled to each diamond pillar.

2. The sensing system of claim 1 wherein at least some of the diamond pillars have different heights.

3. The sensing system of claim 2 comprising respective different height shims coupled between the sensor substrate and adjacent portions of the corresponding input and output optical waveguides.

4. The sensing system of claim 1 wherein the plurality of input and output optical waveguides are arranged in parallel rows.

5. The sensing system of claim 1 wherein the sensor substrate comprises a diamond substrate.

6. The sensing system of claim 5 wherein the diamond substrate comprises a bulk diamond substrate; and wherein the plurality of diamond pillars is integrally formed with the bulk diamond substrate.

7. The sensing system of claim 1 comprising a sensing circuit coupled to the plurality of input and output optical waveguides.

8. The sensing system of claim 1 comprising Photonic Integrated Circuit (PIC) substrate supporting the sensor substrate.

9. The sensing system of claim 1 wherein each input optical waveguide comprises an input optical fiber and an input photonic wire bond coupling the input optical fiber to the corresponding diamond pillar; and wherein each output optical waveguide comprises an output optical fiber and an output photonic wire bond coupling the output optical fiber to the corresponding diamond pillar.

10. A sensing system comprising:
a diamond substrate;
a plurality of diamond pillars on the diamond substrate in an irregular arrangement, each diamond pillar comprising at least one nitrogen vacancy center (NVC); and
a respective pair of input and output optical waveguides coupled to each diamond pillar defining a plurality of parallel rows of input and output optical waveguides.

11. The sensing system of claim 10 wherein at least some of the diamond pillars have different heights.

12. The sensing system of claim 11 comprising respective different height shims coupled between the sensor substrate and adjacent portions of the corresponding input and output optical waveguides.

13. The sensing system of claim 10 wherein the diamond substrate comprises a bulk diamond substrate; and wherein the plurality of diamond pillars is integrally formed with the bulk diamond substrate.

14. The sensing system of claim 10 comprising a sensing circuit coupled to the plurality of input and output optical waveguides.

15. The sensing system of claim 10 comprising Photonic Integrated Circuit (PIC) substrate supporting the diamond substrate.

16. A method of making a sensing device comprising:
forming a plurality of diamond pillars on a sensor substrate in an irregular arrangement, each diamond pillar comprising at least one nitrogen vacancy center (NVC); and
coupling a respective pair of input and output optical waveguides to each diamond pillar.

17. The method of claim 16 comprising identifying locations of the NVCs.

18. The method of claim 17 wherein the sensor substrate comprises a bulk diamond substrate; and comprising etching the bulk diamond substrate to form the plurality of diamond pillars aligned with the locations of the identified NVCs.

19. The method of claim 16 comprising forming at least some of the diamond pillars to have different heights.

20. The method of claim 19 comprising coupling respective different height shims between the sensor substrate and adjacent portions of the corresponding input and output optical waveguides.

21. The method of claim 16 comprising coupling a sensing circuit to the plurality of input and output optical waveguides.

22. The method of claim 16 comprising supporting the sensor substrate on a Photonic Integrated Circuit (PIC) substrate.
